(19) United States
(12) Patent Application Publication
(10) Pub. No.: US 2025/0241037 A1
(43) Pub. Date: Jul. 24, 2025

(54) SELF-ALIGNED SOURCE CONTACT FOR SIC SWITCH UTILIZING OXIDATION RATE DIFFERENCE BETWEEN POLY-SI AND SIC

(71) Applicant: MaxPower Semiconductor, Inc., San Jose, CA (US)

(72) Inventors: Jun Zeng, Redondo Beach, CA (US); Shih-Tzung Su, Torrence, CA (US); Mohamed Darwish, Campbell, CA (US)

(73) Assignee: MaxPower Semiconductor, Inc., San Jose, CA (US)

(21) Appl. No.: 18/972,058

(22) Filed: Dec. 6, 2024

Related U.S. Application Data
(60) Provisional application No. 63/623,065, filed on Jan. 19, 2024.

(51) Int. Cl. H10D 64/01; H01L 21/02; H01L 21/04; H10D 30/66; H10D 62/832; H10D 64/23; H10D 64/66

(52) U.S. Cl. CPC H10D 64/01; H01L 21/02236; H01L 21/049; H10D 64/258; H10D 64/661; H10D 30/66; H10D 62/8325

(57) ABSTRACT

A SiC vertical power switch is formed with planar polysilicon gates. For forming the source metal contact opening over the N+ sources, the large difference in oxidation rates of the planar polysilicon gate and the SiC surface of the N+ source is utilized. A blanket (no mask) oxidation step forms a relatively thick oxide layer over the top of the polysilicon gates and along the side edges of the polysilicon gates, while the oxide formed over the exposed SiC source regions is much thinner. A short blanket etch (no mask) is then used to remove the very thin oxide layer over the source regions. The source metal is then deposited over the insulated gates and the exposed N+ source, where the source metal is self-aligned to the gate so as to have a very repeatable and optimally minimum spacing for a maximum cell density.

### CROSS REFERENCE TO RELATED APPLICATIONS

This application claims priority from U.S. provisional application Ser. No. 63/623,065, filed Jan. 19, 2024, by Jun Zeng et al., incorporated herein by reference.

### FIELD OF INVENTION

The present invention relates to a silicon-carbide (SiC) power semiconductor device, such as a vertical SiC MOSFET using a planar gate with an array of cells, and more particularly, to such a power semiconductor device that can have a higher density of cells by forming the source metal electrode using self-aligned techniques.

### BACKGROUND

Power MOSFETs are widely used as switching devices in many electronic applications for power management and switching control. Vertical MOSFETs have especially high power capabilities due to the ability to form thick drift regions that can deplete to support a high voltage.

One type of vertical MOSFET uses planar gates that create a conductive horizontal channel (by inversion) through a P-body (or P-well), where the current then travels in a substantially vertical path to a bottom drain electrode. Such planar-gate MOSFETs are in contrast to MOSFETs that use vertical trenched gates. The present invention relates to the planar gate variety of a vertical SiC MOSFET. The planar gate variety is generally easier and less expensive to manufacture.

Silicon is a common semiconductor material for a MOSFET. However, SiC has a higher breakdown voltage and can thus be higher doped for lower on-resistance. There are other advantages in using SiC. Unfortunately, SiC has an inversion channel electron mobility that is lower than that of a silicon MOSFET, causing a higher resistance in the SiC channel. To offset this disadvantage of SiC, the cell density can be increased.

However, increasing the cell density above a certain point is difficult due to the required mask alignments to form the P-well (for an N-channel device), N+ sources, P+ body contacts, planar polysilicon gates, and contact openings.

Therefore, what is needed in the field of SiC planar gate power devices is a technique that can increase cell density.

FIGS. 1-9 are used to describe one prior art process used to form a vertical SiC power device using planar gates.

FIG. 1 is a cross-section of a single cell in a prior art, vertical SiC power device during fabrication. A SiC substrate 12 is a highly doped N++ type. A lower-doped SiC buffer layer 14 is formed over the substrate 12. A lower-doped N-type SiC drift layer 16 (or region) is epitaxially grown over the buffer layer 14.

A photoresist 18 (or other suitable masking material) is deposited, masked, and etched to define the locations of the various regions and gates. A P-dopant implant 20 is conducted, and the dopants are driven in to form a P-well 22 (FIG. 2). A well is sometimes also referred to as a body. An oxide layer 24 is deposited.

In FIG. 2, a layer of polysilicon is deposited and blanket etched to form a self-aligned polysilicon spacer 26. An N-dopant implant 28 is then conducted using the spacer 26 as a mask, and the dopants are driven in to form the N+ source regions 30.

In FIG. 3, the surface is masked (not shown) for a P-dopant implant and drive-in to form a P+ body contact region 31. The surface is etched to remove the previous layers, followed by growing a gate oxide layer 32.

In FIG. 4, a layer of doped polysilicon is deposited, masked, and etched to form the conductive polysilicon gates 34.

In FIG. 5, a layer of oxide 36 is deposited.

In FIG. 6, a photoresist layer 38 is deposited, masked, and etched to expose the oxide 36 over a portion of the N+ source region 30 for a source metal contact area 39. The exposed oxide 36 is etch away to expose a portion of the N+ source region 30.

In FIG. 7, the photoresist layer 38 is removed.

In FIG. 8, a blanket RIE etching step is used to form a recessed source contact area 40 that allows the source metal to contact the N+ source regions 30 and the P+ body contact regions 31.

In FIG. 9, the source metal 44 is deposited to contact the N+ source regions 30 and the P+ body contact regions 31.

When the source metal 44 is positively biased with respect to the N++ substrate 12 (having a bottom drain metal electrode that is not shown), and the gate 34 is biased above the turn-on threshold voltage, the P-well 22 (or P-body) under the gate 34 is inverted to form a generally horizontal conductive channel. This channel creates a current path between the N+ source regions 30 and the N-type epitaxial drift layer 16. The current path is then generally vertical to the N++ substrate 12 and the bottom drain electrode.

As seen, there is at least one masking alignment step that is used to define the source metal contact area 39 (FIG. 6). Due to the masking alignment tolerances, the source metal contact area 39 is spaced further from the polysilicon gate 34 than required, which limits the cell density, resulting in an increased on-resistance. It is desirable to avoid such a masking step and replace it with a precision self-alignment step to space the N+ source contact area closer to the polysilicon gate to allow an increased cell density.

### SUMMARY

In embodiments of the present invention, self-alignment techniques are used to form various semiconductor regions in a vertical SiC power device and to form the source metal contact area for the N+ source regions. Such self-alignment techniques do not require mask alignments, resulting in the ability to increase cell density and decrease on-resistance.

For forming the source metal contact opening over the N+ source regions, the difference in oxidation rates of the planar polysilicon gate and the SiC surface of the N+ source region is utilized. The oxidation rate of polysilicon is more than thirty times greater than the oxidation rate of SiC. A blanket (no mask) oxidation step is use to form an oxide layer (e.g. 320 nm) over the top of the polysilicon gates and along the sides edges of the polysilicon gates, while the oxide formed over the exposed SiC source regions is inherently much thinner (e.g. 8 nm). A short blanket etch (no mask) is then used to remove the very thin oxide layer over the source regions while having a negligible effect on the oxide abutting the polysilicon gate. The source metal is then deposited over the insulated gates and the exposed N+ source regions, where the source metal is self-aligned to the gate so as to have a very repeatable and optimally minimum spacing for a maximum cell density.

Other embodiments are disclosed.

### BRIEF DESCRIPTION OF DRAWINGS

FIG. 1 is a cross-section of a single cell in a prior art, vertical SiC power device while the wafer is masked for a P-dopant implant to form a P-well.

FIG. 2 illustrates the cell after a polysilicon layer is deposited and etched to form a self-aligned polysilicon spacer, followed by an N-dopant implant to form the self-aligned N+ source regions.

FIG. 3 illustrates the wafer after using a masking step to implant P-dopants to form the P+ body contact regions, then etching the surface to remove the previous layers, followed by growing a gate oxide layer.

FIG. 4 illustrates a masking and deposition step to form the doped polysilicon gates.

FIG. 5 illustrates a blanket oxide deposition step.

FIG. 6 illustrates etching the deposited oxide and gate oxide over the N+ source regions using a patterned photoresist masking step.

FIG. 7 illustrates the wafer after the photoresist is removed.

FIG. 8 illustrates a blanket RIE etching step used to form a recessed source contact area that allows the source metal to contact the N+ source regions and the P+ body contact regions.

FIG. 9 illustrates the source metal deposited to contact the N+ source regions and the P+ body contact regions.

FIG. 10 is a duplicate of FIG. 5, which may be obtained by the methods of FIGS. 1-4 or by non-conventional methods.

FIG. 11 illustrates the formation of a self-aligned oxide spacer along the edge of the polysilicon gate in accordance with one embodiment of the invention.

FIG. 12 illustrates the growth of an oxide layer, where the oxidation rate over the polysilicon gate is more than thirty times greater than the rate over the SiC source regions, followed by a blanket etch of the surface to remove the thin oxide from the SiC surface.

FIG. 13 illustrates the deposition of the source metal. Note how the source metal is laterally much closer to the edge of the polysilicon gate compared to FIG. 9, allowing a greater cell density.

FIG. 14 illustrates another embodiment of the invention where there is a self-aligned etch after FIG. 12 that removes a portion of the N+ source region and P+ body contact region for a recessed source contact area.

FIG. 15 illustrates another embodiment of the invention where a deep P+ body contact is first formed below the SiC surface, and a self-aligned etch is performed for a deeper recessed source contact area.

FIG. 16 is a top-down view of two cells, including the cell of FIG. 13, 14, or 15, in a much larger 2-dimensional array of cells, forming the vertical SiC power device with planar gates.

Elements that are the same or equivalent in the various figures are labeled with the same numeral.

### DETAILED DESCRIPTION

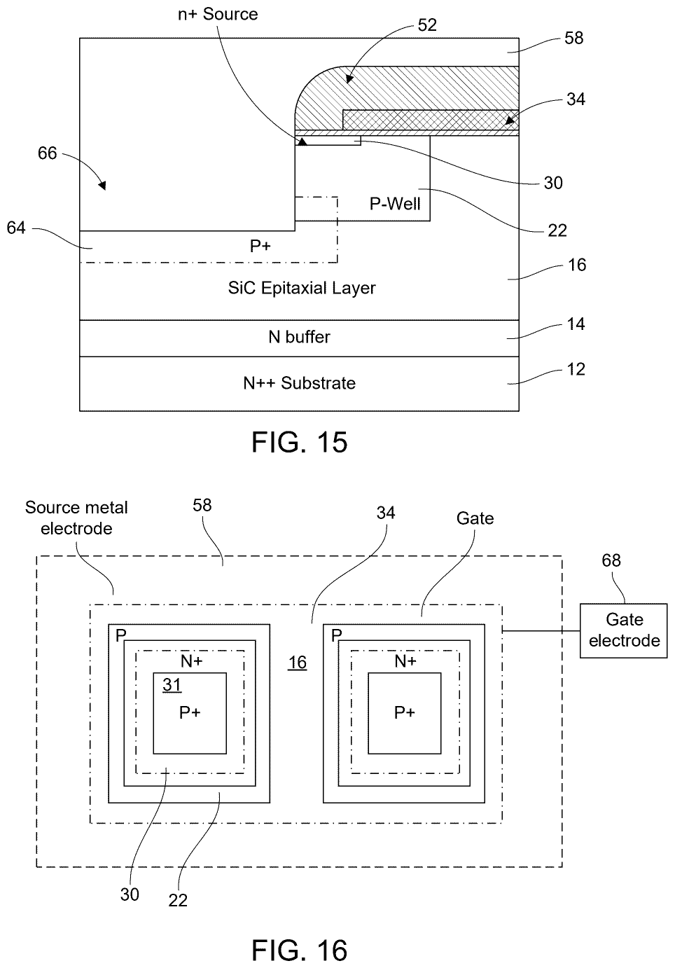

FIGS. 10-13 illustrate steps used to form a vertical SiC power device with planar gates in accordance with one embodiment of the invention. FIGS. 14 and 15 illustrate variants of the method of FIGS. 10-13.

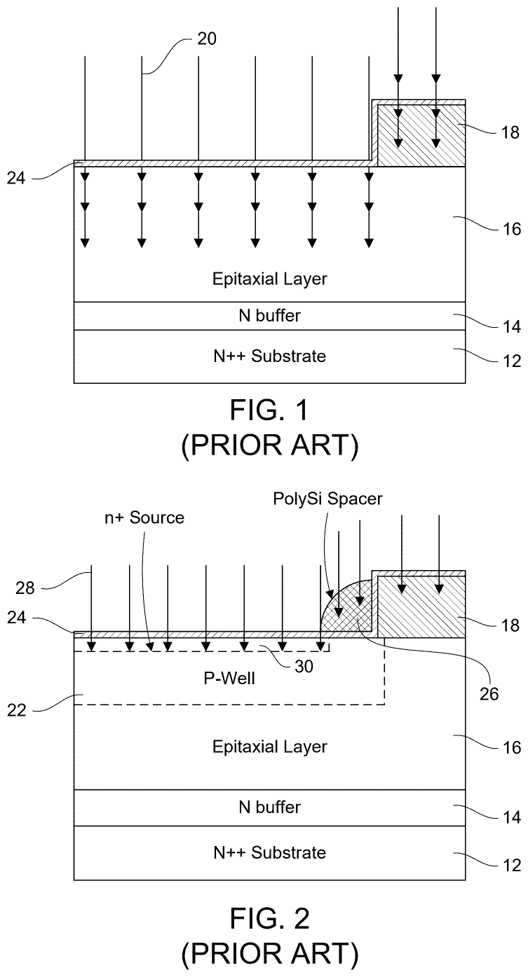

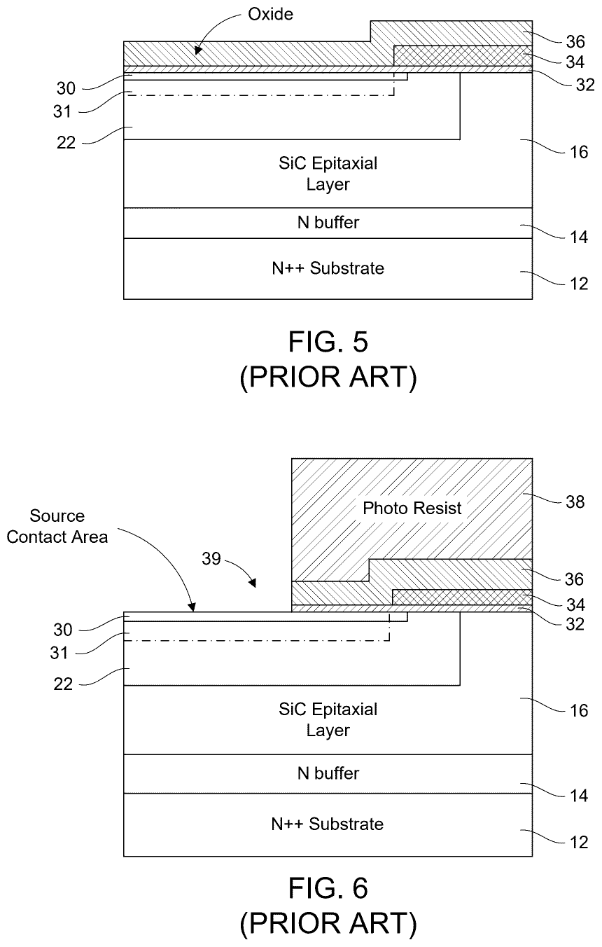

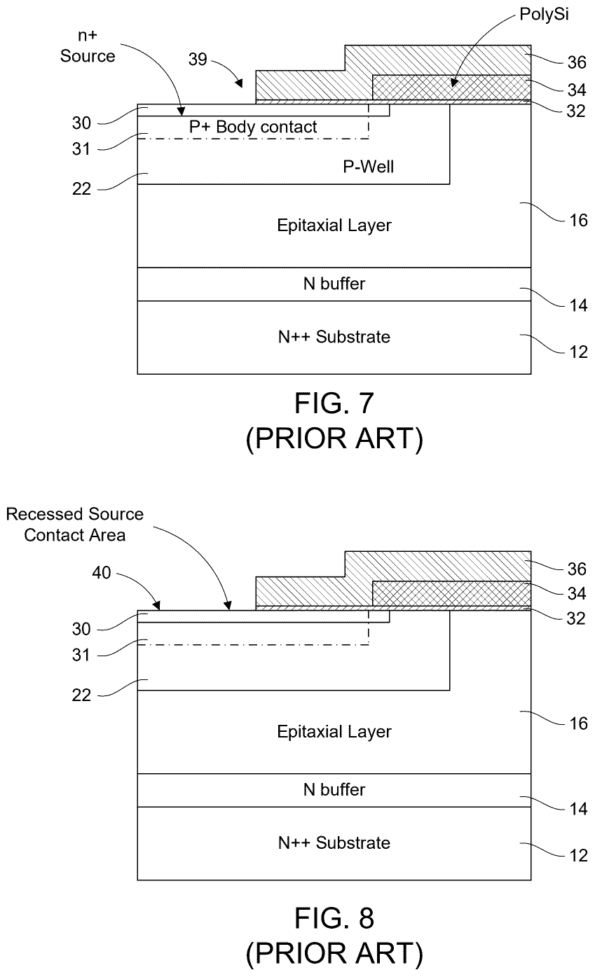

The cross-section of FIG. 10 may be obtained using the steps of FIGS. 1-5 or other methods.

Unlike prior art FIG. 6 which used a mask alignment step to pattern a photoresist layer to define the source metal contact area, the inventive process uses a self-alignment step (no mask) to avoid such mask alignment tolerances.

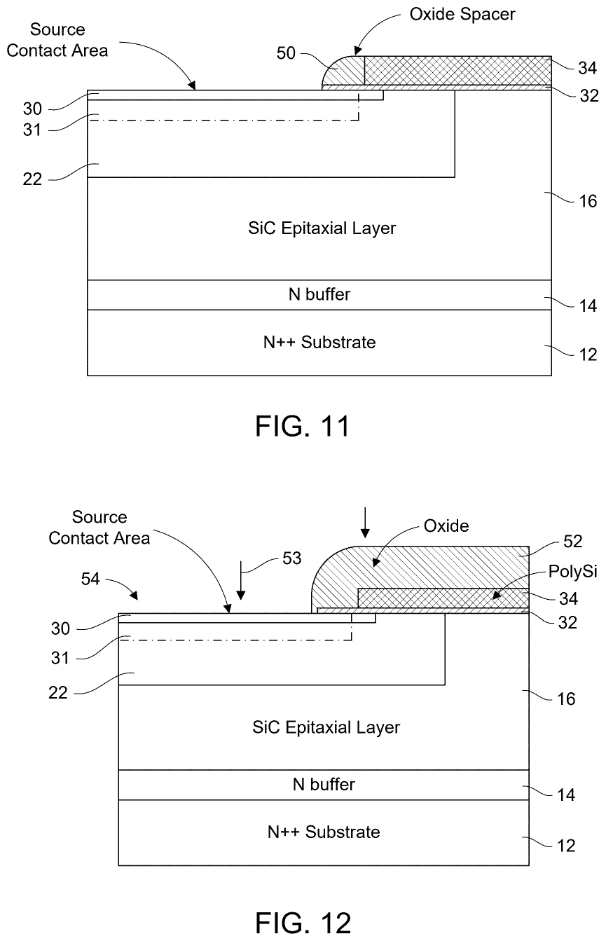

In FIG. 11, the deposited blanket oxide 36 in FIG. 10 is anisotropically blanket etched, using an unmasked dry etch, until the oxide 36 over the polysilicon gate 34 and over the N+ source regions 30 is removed. Techniques for etching oxide anisotropically are well known. What remains is the thicker oxide that was formed near the side edge of the gate 34. This remaining oxide is a self-aligned oxide spacer 50, which is precisely defined and repeatable from lot to lot.

In FIG. 12, the wafer is subjected to a low temperature (e.g., less than 950 degrees C.) wet oxidation process for growing oxide on the exposed surfaces. The oxidation rate of polysilicon is more than thirty times that of SiC. As a result, the oxide 52 grown over the polysilicon gates 34 (e.g., 320 nm for a one-hour process) will be more than thirty times thicker than the oxide grown over the SiC surface (e.g., 8 nm).

Other processes for growing oxide (rather than depositing oxide) may be used. When an oxide is grown, part of the semiconductor surface is converted to SiO2, so the oxide grows into and above the semiconductor. If the oxide was deposited (rather than grown), it would substantially only be deposited on the surface of the semiconductor material. A dry or wet oxide growth process may be used with the invention.

A short blanket etch 53 (wet or dry) is then used to remove the oxide from the SiC surface of the N+ source regions 30 to create the final source contact area 54. Such a blanket etch is generally used anyway for a pre-metal clean step before depositing a metal layer, so no extra step is required.

At this point, another etch may be used to recess the exposed N+ source regions 30 to form a recessed source contact area similar to that of the recessed source contact area 40 of FIG. 8, or no such etch is used if contact to the P+ body contact region 31 is obtain in another manner.

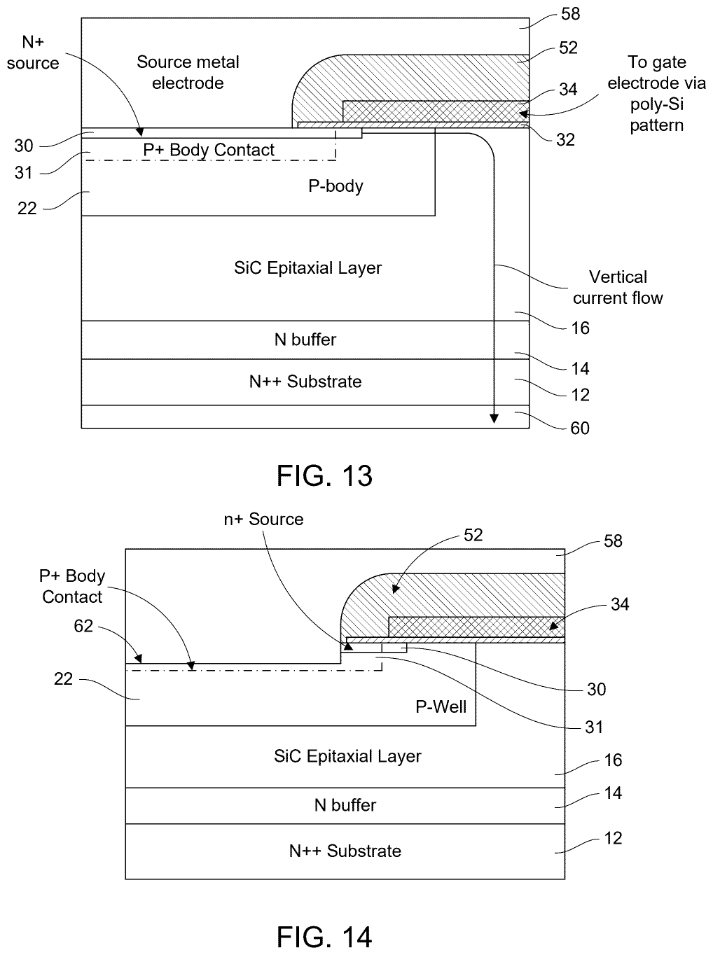

In FIG. 13, the source metal 58 is deposited to contact the N+ source regions 30. In other areas (not shown), the P+ body contact regions 31 may also be contacted by the source metal 58 to weakly short the P-body 22 to the source regions 30.

The substrate 12 may be ground down to reduce on-resistance, and a drain metal 60 is deposited. As shown in FIG. 13, when the device is biased on, the current flows generally horizontally through the inverted channel and then generally vertically to the drain metal 60.

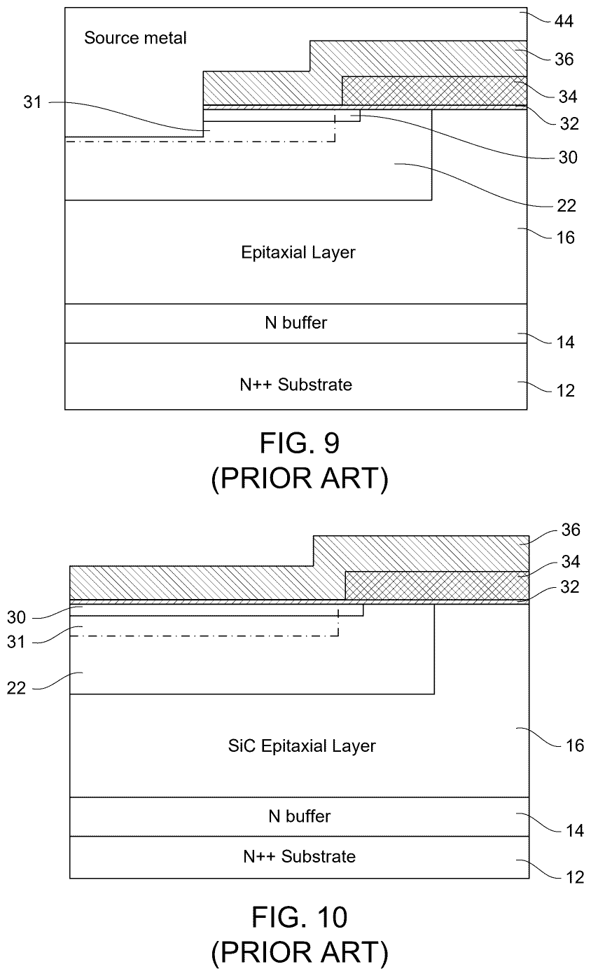

Note that the lateral gap between the polysilicon gate 34 and the source metal 58 is smaller than the gap shown in FIG. 9, due to the elimination of a masking step and its alignment tolerance. This allows each cell to be made smaller so a higher cell density can be achieved. A higher cell density equates to a higher current that can be conducted and a lower on-resistance.

FIG. 14 illustrates another embodiment. After the structure of FIG. 12 is fabricated, a self-aligned blanket SiC etch is performed, such as by RIE, to etch through the N+ source region 30 and partially etch through the P+ body contact region 31. No mask is needed. Any etching of the oxide 52 is trivial, since the etch rate of SiC during the RIE etch is over 20 greater than the etch rate of oxide 52. This forms a recessed source contact area 62.

The source metal 58 is then deposited to contact the exposed side of the N+ source region 30 and the exposed top surface of the P+ body contact region 31.

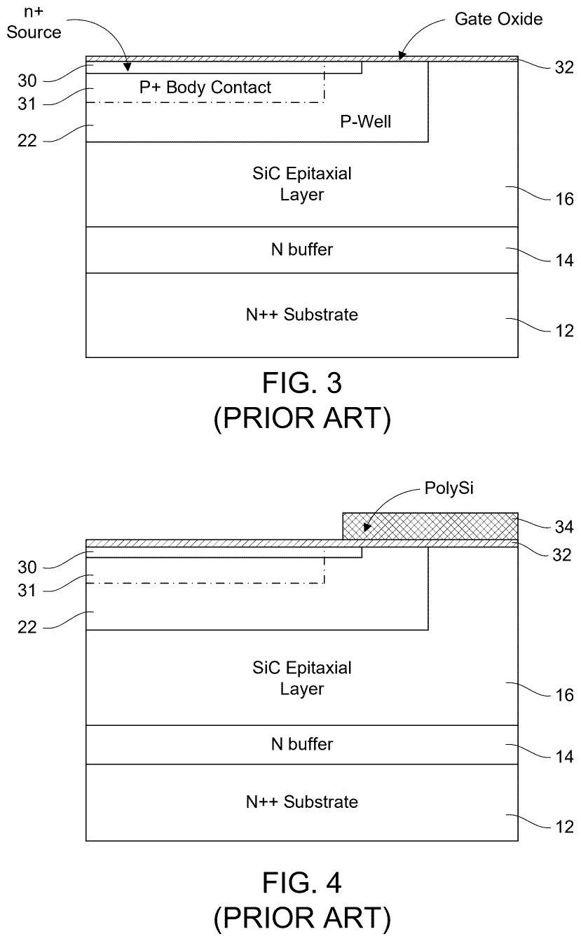

FIG. 15 illustrates another embodiment. During the step illustrated in FIG. 3, rather than performing a shallow P-dopant implant to form the shallow P+ body contact region 31, a deep (higher energy) P-dopant implant is performed, followed by a drive-in step, to form a deep P+ body contact region 64. Part of the P+ body contact region 64 resides in the P-well 22. After the oxide 52 is formed in FIG. 12, a self-aligned blanket SiC etch is performed, such as by RIE, to etch through the N+0 source regions, the P-well 22, and into the P+ body contact region 64. No mask is needed. This forms a deep recessed source contact area 66.

The source metal 58 is then deposited to contact the sides of the N+ source region 30, the P-well 22, and the exposed surface of the P+ body contact region 64.

In a variation of FIG. 15, the deep P+ body contact region 64 is formed during the growth of the drift layer 16. During the epitaxial growth process, a shallow masked P-dopant implant is performed to form the P+ body contact region 64, and the remainder of the epitaxial layer is then grown.

FIG. 16 is a schematic top-down view of two adjacent cells in a large 2-dimensional array of cells that are connected in parallel. The source metal 58 is made transparent. The gates 34 are between the squares and form channels on all sides of the square cells. The cells may form an array of squares, hexagons, strips, or other shapes. The gates 34 are connected to a gate electrode 68.

Any of the embodiments of FIGS. 13, 14, and 15 may be the cells in FIG. 16.

In another embodiment, a deep N++ sinker may be used to contact the N++ substrate 12 to allow the formation of a drain contact at the top of the wafer. In this way, both the source and drain metal electrodes are on the top surface. The device may still be classified as a vertical power device since current flows through the drift layer vertical, then flows horizontally through the substrate, and then flows vertically again through the sinkers to the surface drain electrode.

The N-channel device may be made a P-channel device by reversing the conductivity types.

The substrate 12 can be made P-type to form another type of device.

In a prior art device where oxide is deposited (rather than grown) over the polysilicon gate to insulate the source electrode from the gate, the method of forming the deposited oxide (using a wet process or CVD process) can be determined by reverse engineering. In the present invention, where the oxide is grown over the polysilicon gate, the physical characteristics of the grown oxide are different from those of the deposited oxide. For example, the dielectric properties of grown oxide are much better than those of deposited oxide. Also, with a grown oxide, the oxide will extend more into the surface of the polysilicon gate since the Si in the polysilicon is used to form the SiO2. Therefore, there is a detectable physical difference between the final product using prior art techniques and the inventive technique.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention. The order of steps in the claims does not necessarily limit the claim to that particular order of steps or require that particular order to achieve the desired inventive result.

What is claimed is:

1. A method for forming a silicon carbide (SiC) power switch comprising:
forming a body region of a first conductivity type over a drift region of a second conductivity type;
forming a source region of the second conductivity type overlying the body region, the source region having a SiC surface;
forming a gate oxide layer at least over a portion of the body region;
forming a planer, conductive polysilicon gate over the gate oxide layer, where the gate overlies at least a portion of the body region and extends at least between the source region and an edge of the body region, and where the gate is configured so that a gate voltage above a threshold voltage forms a conductive channel in the body region below the gate between the source region and the drift region;
forming a first oxide layer over the gate and over the source region;
etching the first oxide layer to form an oxide spacer between a side surface of the gate and the source region;
growing a second oxide layer over the gate and the SiC surface of the source region, wherein an oxidation rate of the polysilicon gate is greater than the oxidation rate of the SiC surface;
blanket etching the second oxide layer to remove the second oxide layer from the SiC surface of the source region; and
depositing a top metal electrode layer over the second oxide layer overlying the gate and contacting the source region.

2. The method of claim 1 wherein the step of depositing the top metal electrode comprises depositing the top metal electrode layer over the second oxide layer overlying the gate and over the SiC surface of the source region.

3. The method of claim 1 further comprising forming a body contact region of the first conductivity type abutting the body region, a first conductivity type dopant concentration in the body contact region being greater than the first conductivity type dopant concentration in the body region.

4. The method of claim 3 wherein the top metal electrode contacts the body contact region.

5. The method of claim 3 further comprising etching through the source region and into the body contact region, to form a recessed source contact area, so that the top metal electrode contacts a surface of the body contact region and a side surface of the source region.

6. The method of claim 5 wherein the step of forming the body contact region comprises forming a deep body contact region within the drift region and partially below the body region.

7. The method of claim 6 further comprising etching through the source region, the body region, and into the body contact region, to form a recessed source contact area, so that the top metal electrode contacts a surface of the body contact region and side surfaces of the source region and body region.

8. The method of claim 6 wherein the step of forming the body contact region comprises performing a deep dopant implant into the drift region after the drift region is formed.

9. The method of claim 6 wherein the step of forming the body contact region comprises performing a dopant implant into the drift region during a time when the drift region is being epitaxially grown, then completing growth of the drift region.

10. The method of claim 1 wherein the power switch comprises an array of cells connected in parallel.

11. The method of claim 10 further comprising a SiC substrate over which the drift region is epitaxially grown.

12. The method of claim 11 further comprising forming a bottom metal electrode on the substrate.

13. The method of claim 11 wherein the substrate is of the second conductivity type.

14. The method of claim 1 wherein the step of growing the second oxide layer comprises a wet oxide growth process.

15. The method of claim 1 wherein the step of growing the second oxide layer comprises a dry oxide growth process.

16. A silicon carbide (SiC) power switch comprising:
a body region of a first conductivity type over a drift region of a second conductivity type;
a source region of the second conductivity type overlying the body region, the source region having a SiC surface;
a gate oxide layer at least over a portion of the body region;
a planer, conductive polysilicon gate over the gate oxide layer, where the gate overlies at least a portion of the body region and extends at least between the source region and an edge of the body region, and where the gate is configured so that a gate voltage above a threshold voltage forms a conductive channel in the body region below the gate between the source region and the drift region;
a first oxide layer grown over the polysilicon gate, where the first oxide layer is formed by:
growing the first oxide layer over the gate and the SiC surface of the source region, wherein an oxidation rate of the polysilicon gate is greater than the oxidation rate of the SiC surface; and
blanket etching the first oxide layer to remove the first oxide layer from the SiC surface of the source region; and
a top metal electrode layer over the first oxide layer overlying the gate and contacting the source region.

17. The switch of claim 16 wherein the top metal electrode is over the first oxide layer overlying the gate and over the SiC surface of the source region.

18. The switch of claim 16 further comprising:
a body contact region of the first conductivity type abutting the body region, a first conductivity type dopant concentration in the body contact region being greater than the first conductivity type dopant concentration in the body region; and
a recessed source contact area, wherein the top metal electrode contacts a surface of the body contact region and a side surface of the source region.

19. The switch of claim 16 further comprising:
a body contact region of the first conductivity type abutting the body region and partially below the body region, a first conductivity type dopant concentration in the body contact region being greater than the first conductivity type dopant concentration in the body region; and
a recessed source contact area, wherein the top metal electrode contacts a surface of the body contact region and side surfaces of the source region and body region.

20. The switch of claim 16 wherein the switch further comprises an array of cells connected in parallel.
